(19) United States
(12) Patent Application Publication
(10) Pub. No.: US 2012/0241978 A1
(43) Pub. Date: Sep. 27, 2012

(54) SEMICONDUCTOR DEVICE AND METHOD OF MANUFACTURING THE SAME

(75) Inventor: Akira MINO, Yokkaichi (JP)

(73) Assignee: Kabushiki Kaisha Toshiba, Tokyo (JP)

(21) Appl. No.: 13/425,730

(22) Filed: Mar. 21, 2012

(30) Foreign Application Priority Data
Mar. 22, 2011 (JP) 2011-062395

(51) Int. Cl. H01L 23/535; H01L 21/768

(52) U.S. Cl. 257/775; 438/640; 257/E23.168; 257/E21.585

(57) ABSTRACT

A semiconductor device including a first insulating film formed above a semiconductor substrate and having a first relative dielectric constant; a second insulating film formed above the first insulating film and having a second relative dielectric constant greater than the first relative dielectric constant; a plurality of columnar plugs extending longitudinally through the first and the second insulating films having a first sidewall extending through the first insulating film and a second sidewall extending through the second insulating film, wherein the second sidewall is tapered; a third insulating film formed above the second insulating film and having a third relative dielectric constant less than the second relative dielectric constant of the second insulating film; trenches extending through the third insulating film and reaching an upper portion of the plugs; and an interconnect wiring comprising metal formed within the trenches and contacting the upper portion of the plugs.

### CROSS-REFERENCE TO RELATED APPLICATION(S)

This application is based upon and claims the benefit of priority from Japanese Patent Application No. 2011-062395, filed on, Mar. 22, 2011 the entire contents of which are incorporated herein by reference.

### FIELD

Embodiments disclosed herein generally relate to a semiconductor device and a method of manufacturing such semiconductor device.

### BACKGROUND

As semiconductor device elements become smaller and denser, widths and pitches of electric interconnects are also becoming smaller. For instance, the diametric dimensions of plugs as well as the spacing between the plugs are becoming smaller. As the plugs become closer together, the capacitance between the adjacent plugs is increased. Further, interlayer insulating film is typically formed over the plugs through which a trench is formed to establish connection with the underlying plugs by filling the trench with an conductive interconnect material. The increased capacitance between the closer spaced plugs and the interconnect material formed in the trenches increases the risk of signal delays.

### BRIEF DESCRIPTION OF THE DRAWINGS

FIG. 1 is a partial equivalent circuit representation of an electrical configuration of the memory cell region according to the first embodiment.

FIG. 2 is a schematic plan view partially illustrating the layout of the lower layers of the memory cell region according to the first embodiment.

FIG. 3 is a schematic plan view partially illustrating the layout of the memory cell region featuring on the upper interconnect structures of the bit line contacts according to the first embodiment.

FIG. 4 is schematic vertical cross sectional view taken along line 4A-4A of FIG. 2.

FIGS. 5, 6, 7, 8, 9, and 10 are vertical cross sectional views corresponding to FIG. 4 and each depict one phase of a manufacturing process flow according to the first embodiment.

FIG. 11 corresponds to FIG. 4 and illustrates a second embodiment.

FIGS. 12, 13, 14, and 15 are vertical cross sectional views corresponding to FIG. 4 and each depict one phase of a manufacturing process flow according to the second embodiment.

FIG. 16 corresponds to FIG. 4 and illustrates a third embodiment.

FIGS. 17, 18, 19, 20, and 21 are vertical cross sectional views corresponding to FIG. 4 and each depict one phase of a manufacturing process flow according to the third embodiment.

### DESCRIPTION

In one embodiment, a semiconductor device is disclosed.

The semiconductor device includes a semiconductor substrate; a first insulating film formed above the semiconductor substrate and having a first relative dielectric constant; a second insulating film formed above the first insulating film and having a second relative dielectric constant greater than the first relative dielectric constant; a plurality of columnar plugs extending longitudinally through the first and the second insulating films having a first sidewall extending through the first insulating film and a second sidewall extending through the second insulating film, wherein the second sidewall is tapered; a third insulating film formed above the second insulating film and having a third relative dielectric constant less than the second relative dielectric constant of the second insulating film; a plurality of trenches extending through the third insulating film and reaching an upper portion of each of the plugs; and an interconnect wiring comprising metal formed within each of the trenches and contacting the upper portion of each of the plugs.

In one embodiment, a method of manufacturing a semiconductor device is disclosed. The method includes forming a plurality of longitudinal holes through a first interlayer insulating film; filling each of the holes with a columnar plug; exposing upper sidewalls of the plugs by removing an upper portion of the first insulating film; slimming the exposed plugs; forming an etch stop film above upper surfaces of the plugs or between the upper sidewalls of the plugs; forming a second interlayer insulating film above the etch stop film, the second interlayer insulating film having a higher etching selectivity to the etch stop film; forming a plurality of trenches each reaching the etch stop film and each of the plugs; and forming an interconnect wiring within each of the trenches, the interconnect wiring contacting the upper portion of each of the plugs.

Embodiments are described hereinafter with references to the accompanying drawings to provide illustrations of the features of the embodiments. Elements that are identical or similar are represented by identical or similar reference symbols across the figures and are not re-described. The drawings are not drawn to scale and thus, do not reflect the actual measurements of the features such as the correlation of thickness to planar dimensions and the relative thickness of different layers.

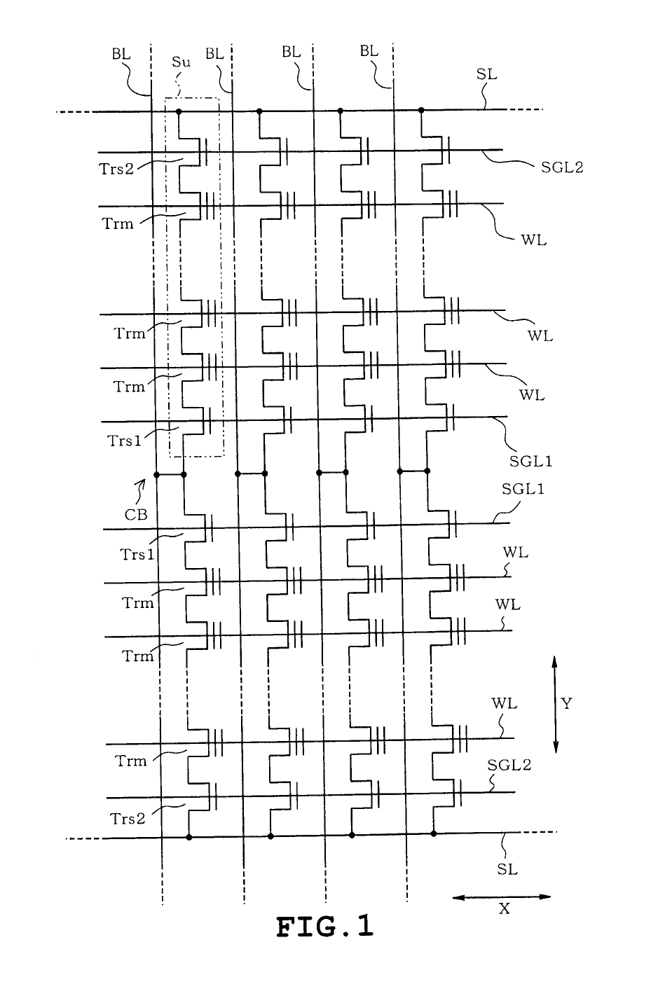

With reference to FIGS. 1 to 10, a description will be given hereinafter on a first embodiment of a semiconductor device through a NAND flash memory application.

First, a description is given on the structure of NAND flash memory. FIG. 1 is a partial equivalent circuit representation of a memory cell array formed in a memory cell region of NAND flash memory 1.

The memory cell array is a collection of units of NAND cells also referred to as NAND cell unit Su or memory cell unit Su arranged in rows and columns. NAND cell unit Su comprises a multiplicity of series connected memory cell transistors Trm, such as 64 in number given by 2ⁿ (n is a positive integer), situated between a couple of select transistors Trs1 and Trs2 that are located at Y-direction ends of NAND cell unit Su. The neighboring memory cell transistors Trm within NAND cell unit Su share their source/drain regions.

The X-direction aligned memory cell transistors Trm shown in FIG. 1 are interconnected by common word line WL, whereas the X-direction aligned select transistors Trs1 are electrically interconnected by common select gate line SGL1 and likewise, the X-direction aligned select transistors Trs2 are electrically interconnected by common select gate line SGL2.

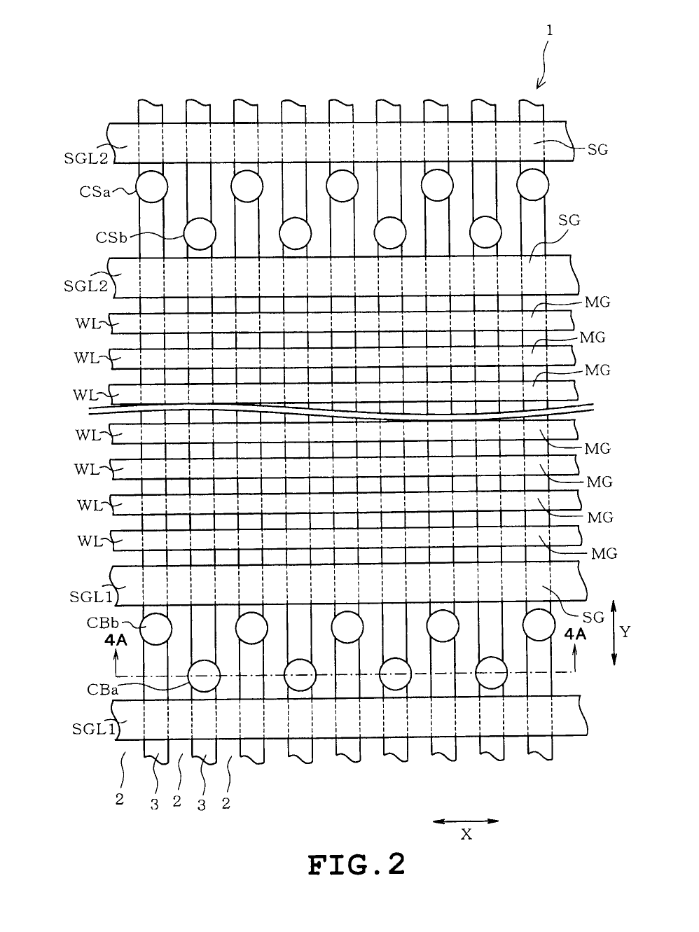

The drain of each select transistor Trs1 is coupled to bit line BL by way of bit line contact CB represented as CBa and CBb in FIG. 2. Bit line BL extends in the Y direction orthogonal to the X direction shown in FIG. 1. The source of select transistor Trs2 is coupled to source line SL extending in the X-direction as shown in FIG. 1.

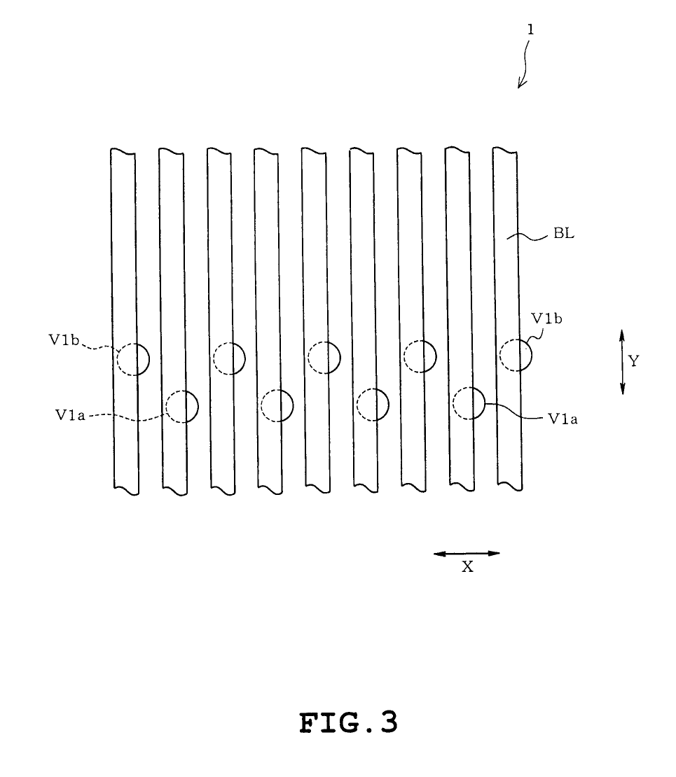

FIGS. 2 and 3 provide planar layouts of the memory cell region in part. FIG. 2 illustrates the surface layer of the semiconductor substrate and layer immediately above the surface layer. FIG. 3 illustrates the layer further above the layer illustrated in FIG. 2.

As shown, multiplicity of isolation regions 2 formed by STI (Shallow Trench Isolation) scheme run in the Y direction as viewed in FIG. 2 of silicon substrate 1, or more generally, semiconductor substrate 1. Isolation regions 2 are separated from one another in the X direction as viewed in FIG. 2 to isolate device areas 3, running in the Y-direction. Multiplicity of word lines WL, spaced from one another in the Y direction by a predetermined spacing, extend in the X direction as viewed in FIG. 2 which is the direction orthogonal to the Y direction in which device area 3 extends.

As shown in FIG. 2, a pair of X directional select gate lines SGL1 each connected to select transistor Trs1 oppose each other in the Y direction. Between the Y directionally opposing select gate lines SGL1, bit line contacts CBa and CBb are formed alternately in each device area 3 so as to be Y-directionally shifted from one another in the adjacent device areas 3 to exhibit a zigzag layout as can be seen in FIG. 2.

Similarly, as shown in FIG. 2, a pair of X directional select gate lines SGL2 each connected to select transistor Trs2 oppose each other in the Y direction. Between the Y directionally opposing select gate lines SGL2, source line contacts CSa and CSb are formed alternately in each device area 3 so as to be Y-directionally shifted from one another in the adjacent device areas 3 to exhibit a zigzag layout as can be seen in FIG. 2. SGL1 and SGL2 are located at opposing Y-direction ends of NAND cell unit Su and thus, are spaced from one another by multiple word lines WL.

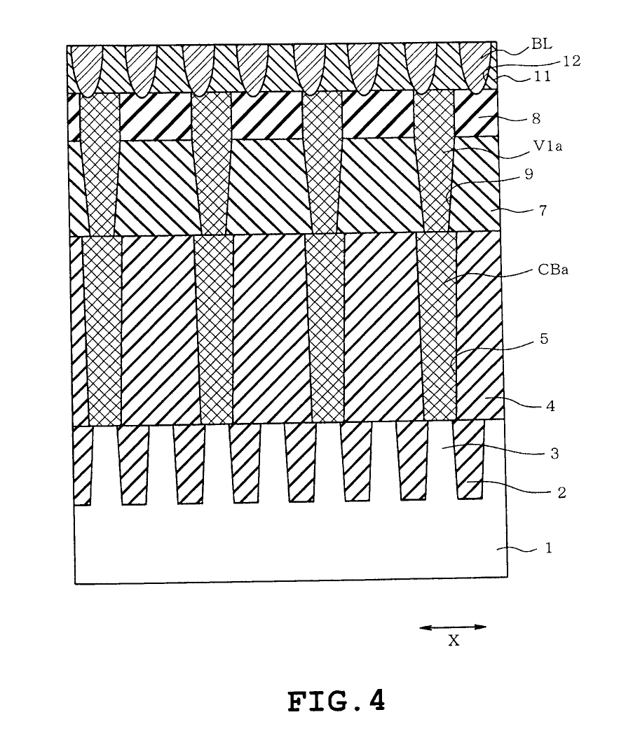

FIG. 4 is a vertical cross section taken along the direction in which select gate line SGL1/SGL2 extends and depicts bit line contact CBa and bit line via plug V1a, extending through the layer above it.

As shown in FIG. 4, the surface layer of semiconductor substrate 1 is isolated into device areas 3 by element isolation trenches. Element isolation region 2 is formed by filling an insulating film such as a silicon oxide film into the element isolation trenches.

Though not shown, gate electrodes of select transistors Trs1 and Trs2 and memory cell transistors Trm are formed above a gate insulating film formed on the upper surface of semiconductor substrate 1.

In the portion shown in FIG. 4, the above described gate electrode structures of transistors Trs1, Trs2 and Trm are removed by etching to form bit line contacts CBa and CBb. After removing the gate electrode structures, silicon oxide film 4 is formed in a predetermined thickness above semiconductor substrate 1 located between the pair of opposing select gate lines SGL1 and between the pair of opposing select gate lines SGL2. The following description will be based on the portion between the opposing select gate lines SGL1 since the portion between the select gate lines SGL2 are configured substantially in the same way.

Silicon oxide film 4 has multiple contact holes 5 penetrating from its upper surface to its lower surface. Contact holes 5 are formed so as to expose every other device area 3 of semiconductor substrate 1 as viewed in FIG. 4. The sidewalls of contact holes 5 are substantially vertical relative to the upper surface of semiconductor substrate 1.

Contact holes 5 extending substantially vertically to bit line contacts CBa and CBb, later filled with contact plugs 6, are formed on every device region 3 shown in FIG. 4 so as to be shifted in the Y direction from the adjacent contact hole 5 to exhibit a zigzag layout as can be seen in the plan view of FIG. 2. As a result, bit line contacts CBa and CBb appear alternately in the X direction as viewed in FIG. 2.

Though the cross sectional view of FIG. 4 only shows contact holes 5 for bit line contact CBa, contact holes 5 for bit line contact CBb are also formed in device region 3 located between the contact holes 5 for bit line contact CBa. Bit line contacts CBa and CBb are arranged in a zigzag layout in plan view to secure sufficient distance between the adjacent contacts CBa and CBb within a smaller geometry in which the device elements as well as the design rules have become smaller. Obtaining sufficient distance between the bit line contacts CBa and CBb improves the device properties by, for instance, reducing the capacitance between the adjacent bit line contacts CBa and CBb.

Contact holes 5 are lined with barrier metal such as a laminate of titanium (Ti) and titanium nitride (TiN) and thereafter filled with contact plug 6 comprising conductive materials such as tungsten (W).

Above silicon oxide film 4, silicon oxide film 7 serving as a first insulating film is formed in a predetermined thickness. Further above silicon oxide film 7, silicon nitride film 8 is formed that serves as an etch stop as well as a second insulating film. In the first embodiment, the second insulating film comprises silicon nitride film 8 but materials such as silicon carbonitride film (SiCN) containing a silicon nitride may be employed instead.

Silicon oxide film 7 and silicon nitride film 8 are penetrated by via holes 9 also referred to as holes that extends from the upper surface of silicon nitride film 8 to the lower surface of silicon oxide film 7 directly above bit line contact CBa.

Via hole 9 is configured to increase its transverse cross sectional area with elevation from the lower surface of silicon oxide film 7 to the upper surface of silicon nitride film 8, meaning that the sidewall of via hole 9 is reverse tapered. Via hole 9 is lined by barrier metal not shown comprising materials such as titanium nitride (TiN) and thereafter filled with bit line via plug V1a comprising conductive materials such as tungsten W.

Thus, bit line via plug V1a extends from the upper surface of silicon nitride film 8 to the lower surface of silicon oxide film 7 like a column extending longitudinally, in other words, in the up and down direction, through silicon nitride film 8 and silicon oxide film 7. Bit line via plug V1a is also referred to as a columnar plug.

Though not shown in the cross sectional view of FIG. 4, bit line via plug V1a is formed directly above contact plug 6 of bit line contact CBb shown in FIG. 2 as can be seen in FIG. 3. The lower surfaces of bit line via plugs V1a and V1b are in direct contact with the upper surfaces of contact plugs 6 of the corresponding bit line contacts CBa and CBb, respectively.

The upper surface of silicon nitride film 8 and the upper surface of bit line via plug V1a are substantially coplanar. Above the upper surfaces of silicon nitride film 8 and bit line via plug V1a, silicon oxide film 11 is formed that serves as a third insulating film and a second interlayer insulating film.

Silicon nitride film 8 and silicon oxide film 11 may be selectively etched relative to the other through adjustment in etch conditions. Silicon oxide film 11 has trench 12 formed into it that extends in the Y direction.

Trench 12 is filled with a conductive material such as copper (Cu) to form bit line BL, which is also referred to as an interconnect wiring. Bit line BL has an X-directional width that partially overlaps with the diameter of the upper surface of bit line via plug V1a as shown in FIG. 3. As shown in FIG. 3, bit line via plug V1a and V1ba are formed alternately on bit line BL.

As shown in FIG. 4, each bit line BL is isolated in the X direction by silicon oxide film 11. Though the lower end of bit line BL extends slightly below the upper surface of silicon nitride film 8, no silicon nitride film 8 is placed in direct contact with upper sidewall of bit line BL and the X-directionally adjacent bit line via plug V1a.

Further, the relative dielectric constants of silicon oxide films 7 and 11 are lower than silicon nitride film 8 or silicon carbonitride film.

The first embodiment configured as described above achieves reduced capacitance coupling between bit line BL and the X-directionally adjacent bit line via plug V1a as compared to a configuration in which silicon nitride film 8 exists between bit line BL and bit line via plug V1a.

Further, because bit lines BL are isolated from one another by silicon oxide film 11 in the first embodiment and no silicon nitride film 8 exists between the adjacent bit lines BL, especially between the upper sidewalls of bit lines BL, capacitance coupling between the adjacent bit lines BL can be reduced. Speed of signal transmission is known to depend on resistance and the capacitance between the interconnect lines. The first embodiment thus, minimizes delays of signal transmission through bit line BL by reducing time constant which is achieved through suppression of capacitance between bit line BL and bit line via plug V1a.

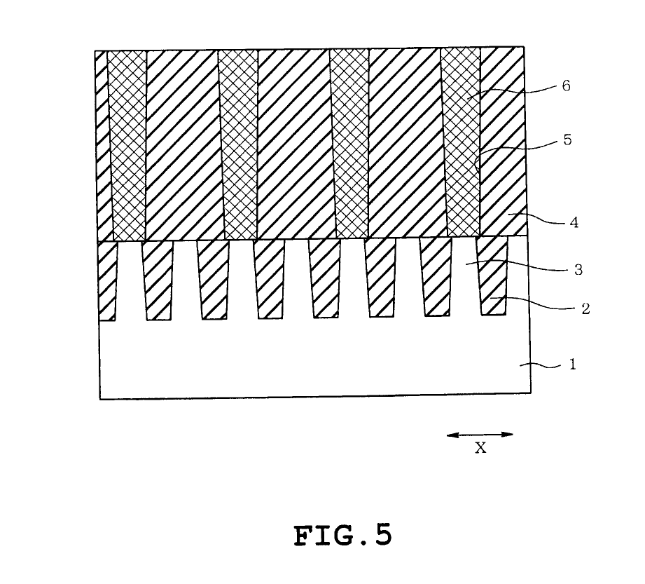

Next, a manufacturing process flow of the above described structure is described with reference to FIGS. 5 to 10. The following descriptions will focus on the formation of bit line via plug V1a and bit line BL and the manufacturing process flow of contact plug 6 will only be briefly described. The descriptions are primarily directed to the features of the first embodiment and thus, known steps may be added or removed from the process flow as required. Further, the sequence of the process flow may be rearranged if practicable.

Referring to FIG. 5, device area 3 is isolated by forming element isolation regions 2 into semiconductor substrate 1. Then, silicon oxide film 4 is deposited by CVD (Chemical Vapor Deposition) which is thereafter anisotropically etched by RIE (Reactive Ion Etching) or the like to form multiplicity of contact holes 5. Each of contact holes 5 are then filled with contact plug 6 which corresponds to bit line contact CBa.

The process shown in FIG. 5 forms contact holes 5 arranged in a zigzag layout in device areas 3 located between a pair of select gate lines SGL1 as shown in FIG. 2. Each of contact holes 5 are located so as to relatively closer to either of the opposing select gate lines SGL1.

The inner surface of each of contact holes 5 is lined with barrier metal comprising a laminate of conductive materials such as titanium (T) and titanium nitride (TiN). Tungsten (W) is further formed along the barrier metal to fill contact hole 5. Then the overflow of tungsten deposited above silicon oxide film 4 is planarized by CMP (Chemcial Mechanical Polishing) to obtain the structure illustrated in FIG. 5.

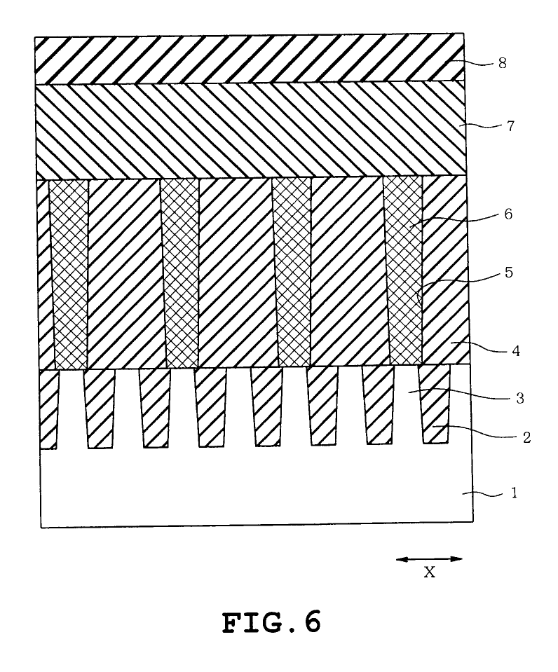

Referring now to FIG. 6, silicon oxide film 7 is deposited by plasma CVD using TEOS (Tetra Ethyl Ortho Silicate) gas. Then, silicon nitride film 8 is deposited above silicon oxide film 7 by plasma CVD.

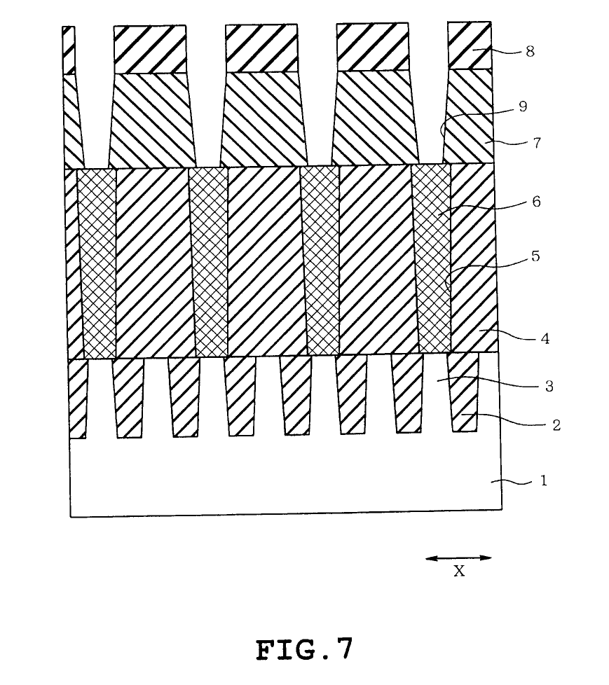

Thereafter, as shown in FIG. 7, resist not shown is formed and patterned above silicon nitride film 8. Then, using the patterned resist as a mask, silicon nitride film 8 is anisotropically etched by RIE. Further, silicon oxide film 7 is anisotropically etched by RIE to obtain via hole 9.

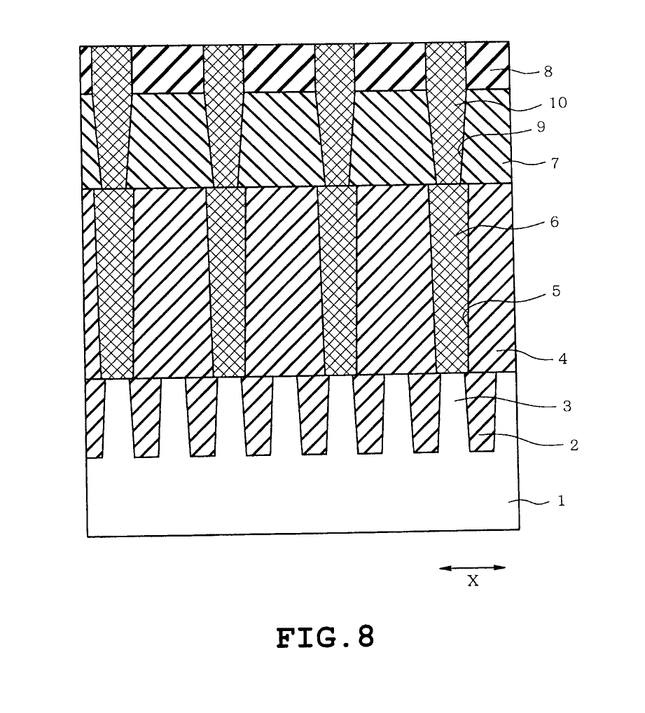

Next, as shown in FIG. 8, a barrier metal made of titanium nitride (TiN) for example is formed along the inner surface of via hole 9 whereafter tungsten (W) is further formed along the barrier metal to fill via hole 9. Then, the overflow of tungsten deposited above silicon nitride film 8 is planarized by CMP (Chemcial Mechanical Polishing) using silicon nitride film 8 as a polish stop to form via plug 10. Via plug 10 corresponds to bit line via plug V1a shown in FIG. 4.

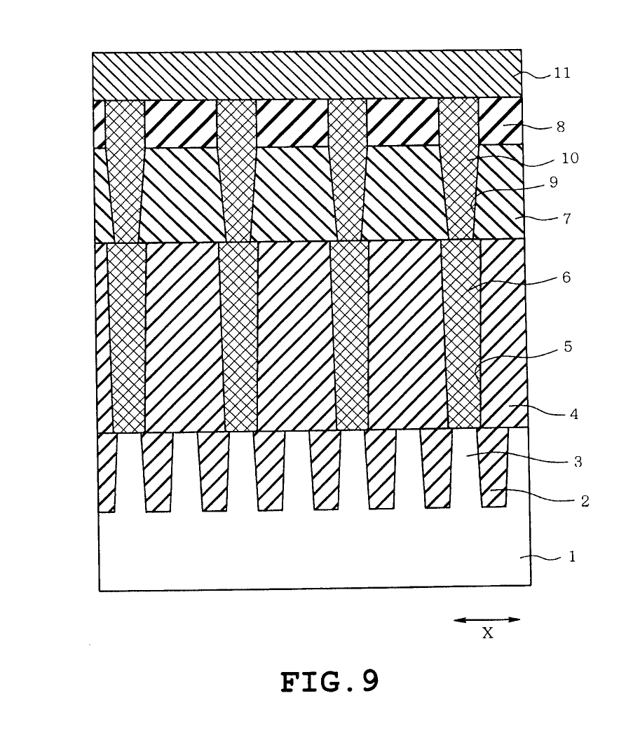

Referring now to FIG. 9, silicon oxide film 11 is deposited by CVD above via plug 10 and silicon nitride film 8.

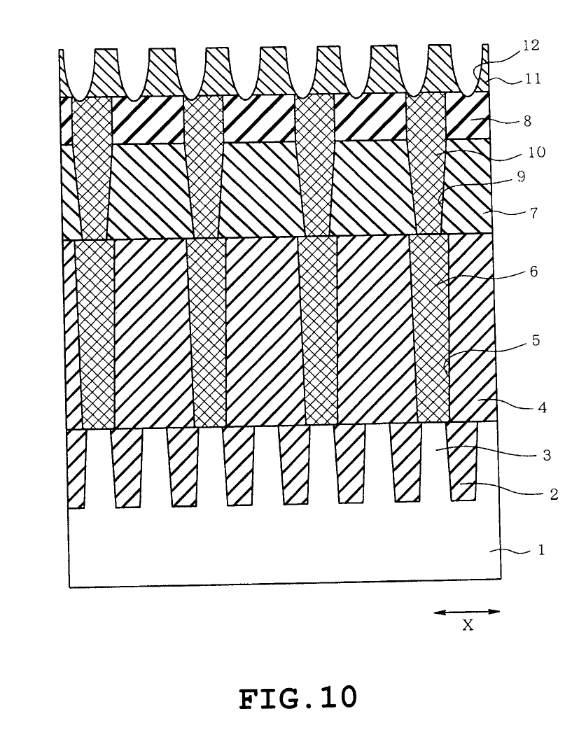

Then, as shown in FIG. 10, resist not shown is formed and patterned above silicon oxide film 11. Then, using the patterned resist as a mask, silicon oxide film 11 is etched to form trench 12 for forming bit line BL. Trench 12 is formed by anisotropically etching silicon oxide film 11 with higher selectivity relative to silicon nitride film 8. The resist pattern is thereafter removed.

The above described selective etching allows the etching to stop substantially at the upper surface of silicon nitride film 8, thereby controlling trenches 12 at a substantially uniform depth.

Next, as shown in FIG. 4, trenches 12 are filled with copper (Cu) serving as an interconnect wiring which is exemplified as bit line BL. Bit line BL is associated with every contact plug 6 which constitutes bit line contacts CBa and CBb.

Because depth of trench 12 filled with the interconnect wiring is substantially constant, the distance between bit line BL, measured from the upper sidewall of bit line BL in particular, and underlying via plug 10 can be kept substantially constant.

Accordingly, the capacitance between bit line BL and via plug 10 can be kept constant to keep the signal delay of signal transmission between multiplicity of bit line BL and via plugs 10 substantially constant. Such uniformity in signal delay prevents property variation.

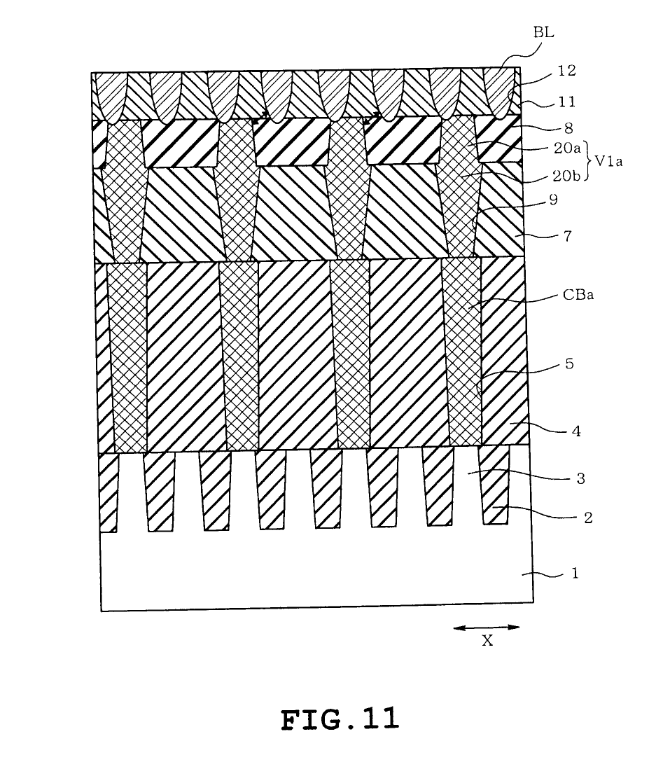

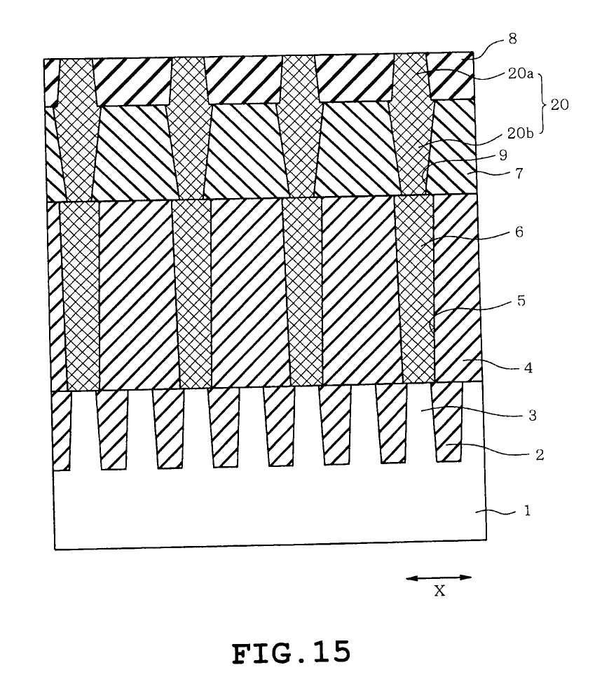

FIGS. 11 to 15 illustrate a second embodiment. The second embodiment differs from the first embodiment in that the upper portion of the via plug is tapered such that the transverse cross sectional area increases from the upper surface of the via plug toward the semiconductor substrate. Elements that are identical or similar to those of the first embodiment are represented by identical or similar reference symbols and are not redescribed. The descriptions given hereinafter focus on the differences from the first embodiment.

As shown in FIG. 11, bit line via plug V1a is formed above bit line contact CBa and is configured by upper portion 20a and lower portion 20b. Lower portion 20b is configured such that its horizontal surface is reduced toward the lower end of silicon oxide film 7 from the upper end of silicon oxide film 7. In other words, lower portion 20b is reverse tapered.

The interface of silicon oxide film 7 and silicon nitride film 8 serves as a boundary between upper portion 20a and lower portion 20b of bit line via plug V1a. Bit line via plug V1a varies its diametric dimension across the boundary as can be seen in FIG. 11 in which the uppermost surface of lower portion 20b is greater in diametric dimension as compared to the lowermost surface of upper portion 20b.

Upper portion 20a reduces its transverse cross sectional area toward the upper surface of silicon nitride film 8 from the lower surface of silicon nitride film 8, meaning that upper portion 20a is tapered, that is, forward tapered as opposed to lower potion 20b which reverse tapered. The upper corner of bit line via plug V1a is in contact with bit line BL.

Because upper portion 20a is tapered, the distance between bit line BL and the adjacent bit line via plug V1a is increased as compared to the first embodiment. Accordingly, the capacitance between bit line BL and upper portion 20a of the adjacent bit line via plug V1a can be reduced.

The second embodiment is also substantially free of silicon nitride film 8, having greater relative dielectric constant than silicon oxide film 7, between bit lines BL and in particular between the upper sidewalls of bit lines BL. Thus, delays of signal transmission through bit line BL can be minimized by reducing time constant which is achieved through suppression of capacitance between bit line BL and bit line via plug V1a.

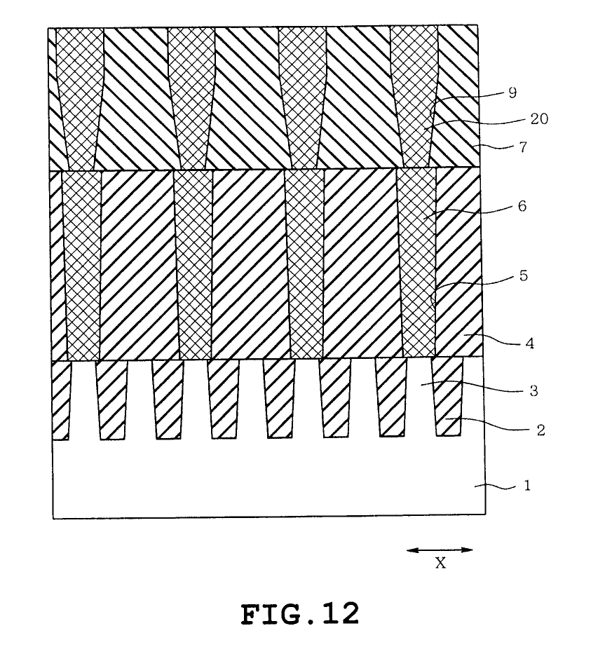

Next, a manufacturing process flow of the above described structure is described with reference to FIGS. 12 to 15. The following descriptions will focus on the formation of bit line via plug V1a and bit line BL and the manufacturing process flow of other elements will not be described.

Referring to FIG. 12, silicon oxide film 7 is deposited by CVD above the upper surface of silicon oxide film 4 and contact plug 6. Then, silicon oxide film 7 is anisotropically etched by RIE to obtain via hole 9. Next, a barrier metal made of titanium nitride (TiN) for example is formed along the inner surface of via hole 9 whereafter tungsten (W) is further formed along the barrier metal to fill via hole 9. Then, the overflow of tungsten is planarized by CMP (Chemcial Mechanical Polishing) to form via plug 20. Via plug 20 corresponds to bit line via plug V1a shown in FIG. 11.

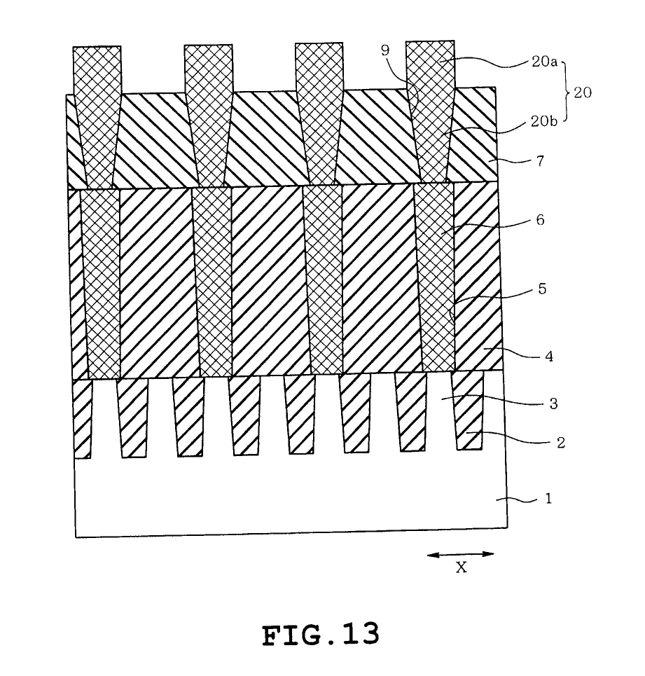

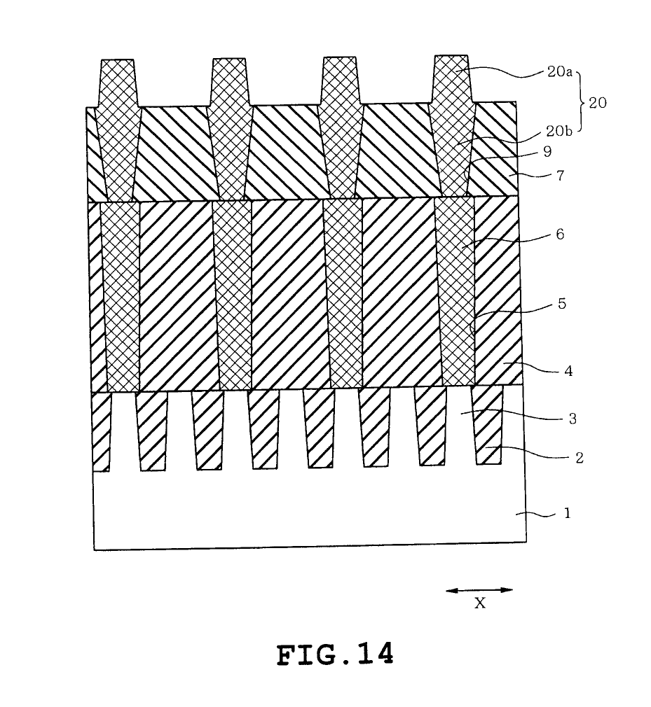

Then, as shown in FIG. 13, the upper portion of silicon oxide film 7 is etched back to expose the sidewall of upper portion 20a of via plug 20. Next, as shown in FIG. 14, the exposed sidewall of upper portion 20a of via plug 20 is slimmed to reduce the diametric dimension of upper portion 20a of via plug 20. The slimming may be carried out by isotropic etching such as CDE (Chemical Dry Etching) after the anisotropic etching by RIE.

Then, silicon nitride film 8 is deposited above silicon oxide film 7 by plasma CVD and thereafter entirely etched back to expose the upper surface of upper portion 20a of via plug 20. The etch back may be replaced by CMP that utilizes the upper surface of upper portion 20a of via plug 20 as a polish stop. The upper surface of upper portion 20a of via plug 20 may be exposed as described above.

Next, as shown in FIG. 11, silicon oxide film 11 is deposited by CVD. Then, trench 12 is formed through silicon oxide film 11 and partially into an upper portion of silicon nitride film 8, as well as into upper portion 20a of via plug 20. Trench 12 is subsequently filled with the interconnect wiring. These processes remain unchanged from the first embodiment and thus, will not be re-described.

When multilevel interconnect structures such as those described above are employed, misalignment of resist masks in the lithography process for instance may cause the entire layer of bit lines BL to be X-directionally displaced from the designed location immediately above bit line via plug V1a.

At this instance, the distance between bit line BL and the adjacent via plug 20 affects the voltage tolerance of the device. In the second embodiment, because the sidewall of upper portion 20a of via plug 20 is slimmed, the distance between via plug 20 and bit line BL is increased, thereby providing the desired voltage tolerance.

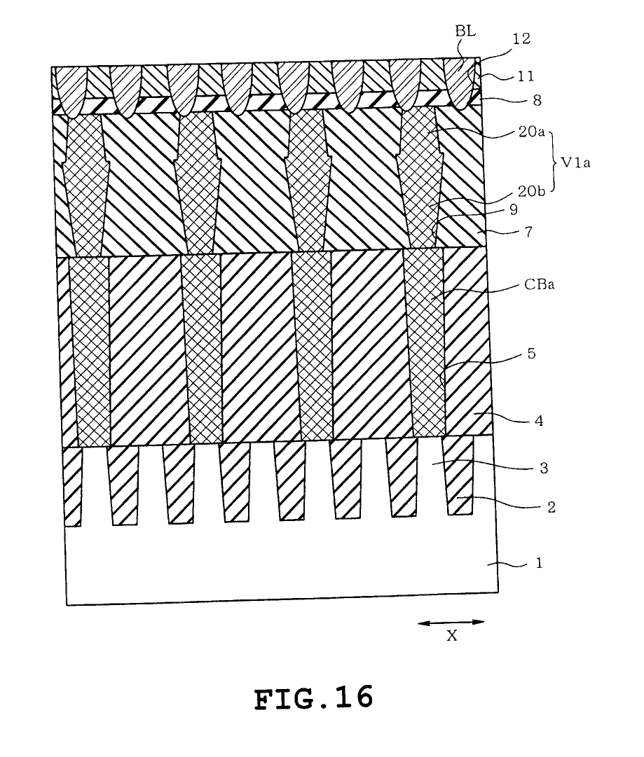

FIGS. 16 to 21 illustrate a third embodiment. The third embodiment differs from the second embodiment in that etch stop film is formed along the upper surface of the via plug. Elements that are identical or similar to those of the first embodiment are represented by identical or similar reference symbols and are not re-described. The descriptions given hereinafter focus on the differences from the second embodiment.

As shown in FIG. 16, bit line via plug V1a is filled in via hole 9 formed through silicon oxide film 7. In the shown structure, silicon oxide film 7 is formed X-directionally beside upper portion 20a of bit line via plug V1a and no silicon nitride film 8 is formed in that portion. Moreover, silicon oxide film 7 is formed along the entire length of the sidewall of bit line via plug V1a.

Silicon nitride film 8 is formed above the upper surface of silicon oxide film 7 and silicon oxide film 11 is further formed above silicon nitride film 8. The upper surface of bit line via plug V1a is substantially level with the lower surface of silicon nitride film 8. Through silicon nitride film 8 and silicon oxide film 11, multiple trenches 12 are formed which are each filled with conductive interconnect material to form bit line BL.

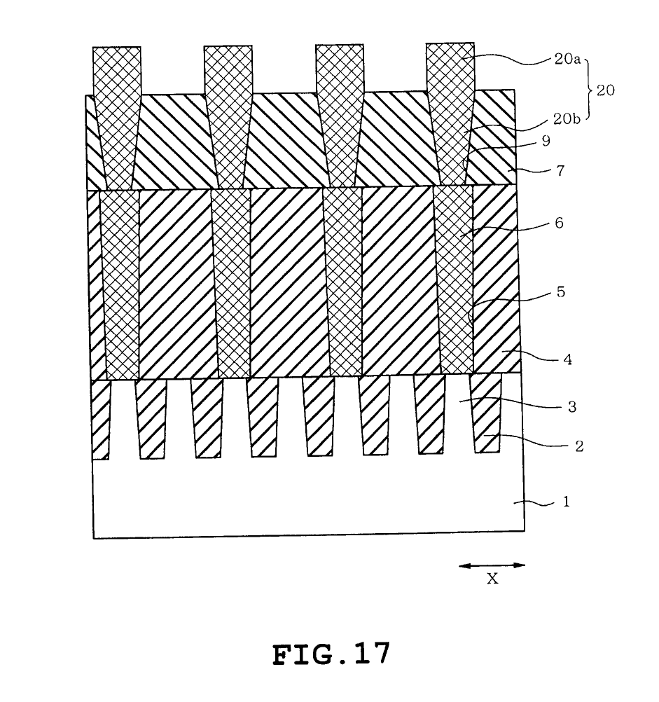

Next, a manufacturing process flow of the above described structure is described with reference to FIGS. 17 to 21. Again, the following descriptions will focus on the formation of bit line via plug V1a and the manufacturing process flow of other elements will not be described.

Referring to FIG. 17, silicon oxide film 7 is deposited above the upper surfaces of silicon oxide film 4 and contact plug 6. Then, silicon oxide film 7 is anisotropically etched by RIE to obtain via hole 9. Next, a barrier metal made of titanium nitride (TiN) for example is formed along the inner surface of via hole 9, whereafter tungsten (W) is further formed along the barrier metal to fill via hole 9. Then, the overflow of tungsten is planarized by CMP (Chemcial Mechanical Polishing) to form via plug 20. Next, the upper portion of silicon oxide film 7 is etched back to lower the upper surface of silicon oxide film 7 to an elevation below the upper surface of upper portion 20a of via plug 20.

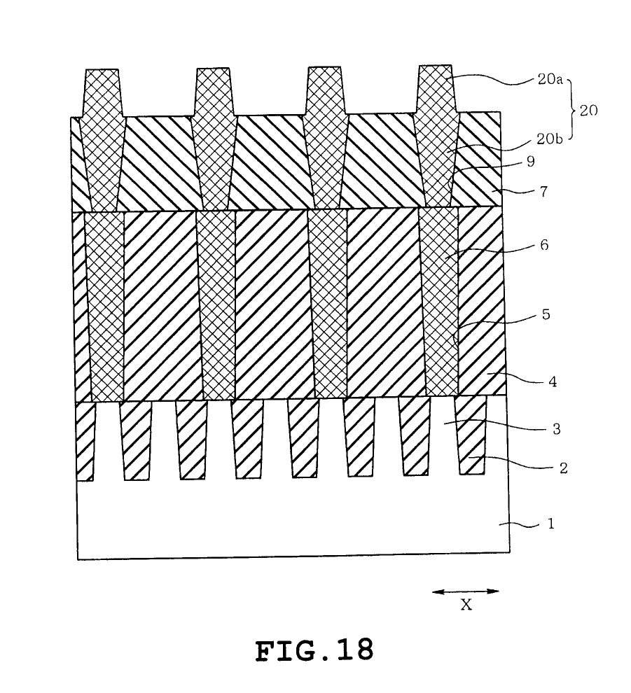

Then, as shown in FIG. 18, upper portion 20a of via plug 20 is slimmed to reduce its diametric dimension. The slimming is carried out as done in the second embodiment.

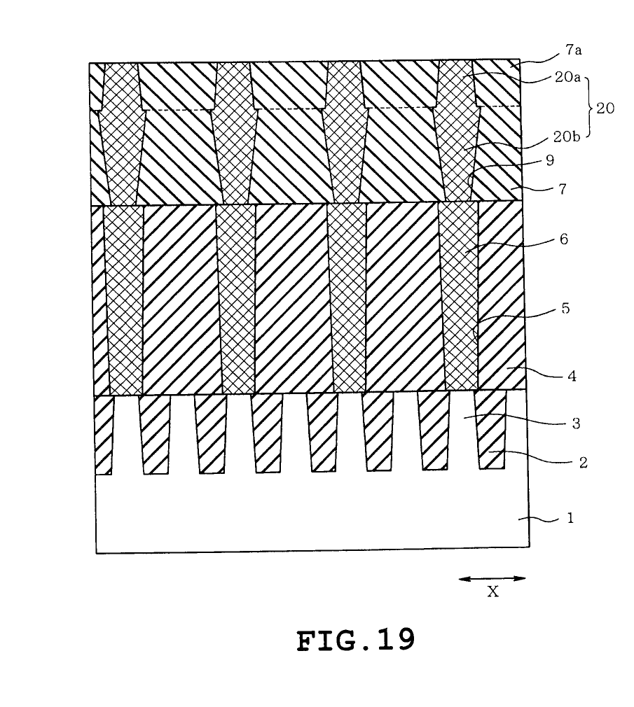

Next, as shown in FIG. 19, silicon oxide film 7a which is substantially homogenous as the existing silicon oxide film 7 is redeposited by plasma CVD to re-cover the sidewall of upper portion 20a of via plug 20. The feature is thereafter entirely etched back to expose the upper surface of upper portion 20a of via plug 20. The etch back for exposing the upper surface of upper portion 20a of via plug 20 may be replaced by CMP that utilizes the upper surface of upper portion 20a of via plug 20 as a polish stop.

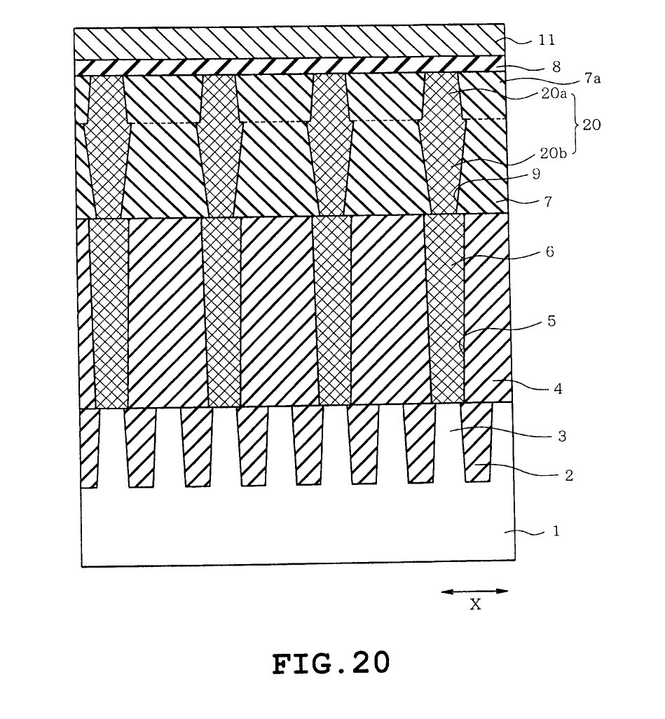

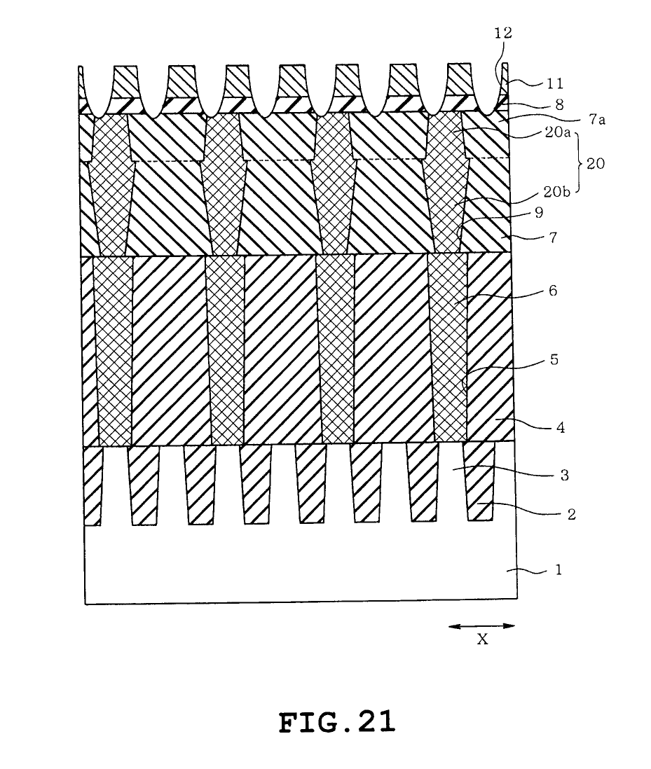

Then, as shown in FIG. 20, silicon nitride film 8 is deposited above silicon oxide film 7, silicon oxide film 7a, and the upper surface of upper portion 20a of via plug 20 by plasma CVD. Thereafter, silicon oxide film 11 is deposited above the upper surface of silicon nitride film 8 by plasma CVD. Then, as shown in FIG. 21, trench 12 is formed through silicon oxide film 11, silicon nitride film 8, and partially into the upper portion of silicon oxide film 7a, as well as into upper portion 20a of via plug 20. Then, trench 12 is subsequently filled with the interconnect wiring as shown in FIG. 16. The above described process flow and the resulting structure also provides the operation and effect provided in the second embodiment.

The present embodiment may be modified or expanded as follows.

Contact plug 6, via plug 10, and via plug 20 having been exemplified to comprise a tungsten film formed along a lining of a barrier metal film may alternatively comprise other conductive materials such as copper or polycrystalline silicon heavily doped with impurities.

Via holes 9 having been exemplified to exhibit a taper need not be tapered.

The embodiments having been directed to bit line contact CB may be directed to source line contacts CS as well to achieve the same operation and effects.

The embodiments having been directed to a NAND flash memory may be directed to a NOR flash memory or semiconductor devices in general that employ a contact plug and a via plug.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate;
a first insulating film formed above the semiconductor substrate and having a first relative dielectric constant;
a second insulating film formed above the first insulating film and having a second relative dielectric constant greater than the first relative dielectric constant;
a plurality of columnar plugs extending longitudinally through the first and the second insulating films having a first sidewall extending through the first insulating film and a second sidewall extending through the second insulating film, wherein the second sidewall is tapered;
a third insulating film formed above the second insulating film and having a third relative dielectric constant less than the second relative dielectric constant of the second insulating film;
a plurality of trenches extending through the third insulating film and reaching an upper portion of each of the plugs; and
an interconnect wiring comprising metal formed within each of the trenches and contacting the upper portion of each of the plugs.

2. The device according to claim 1, wherein the second insulating film includes a silicon nitride.

3. The device according to claim 1, wherein the plugs are arranged in a zigzag layout.

4. The device according to claim 1, wherein the first insulating film includes a silicon oxide.

5. The device according to claim 1, wherein the third insulating film is formed at least between upper sidewalls of adjacent interconnect wirings.

6. The device according to claim 1, wherein the third insulating film includes a silicon oxide.

7. The device according to claim 1, wherein the second insulating film includes a planar portion having an upper surface being coplanar with the upper surface of the plug.

8. The device according to claim 1, wherein each of the trenches partially extends into the upper portion of the plug and an upper portion of the second insulating film.

9. A semiconductor device comprising:
a semiconductor substrate;
a first insulating film formed above the semiconductor substrate and having a first relative dielectric constant;
a second insulating film formed above the first insulating film and having a second relative dielectric constant greater than the first relative dielectric constant;
a plurality of columnar plugs extending longitudinally through the first insulating film and having an upper sidewall and a lower sidewall, each of the plugs having an upper surface substantially level with a lower surface of the second insulating film, wherein the upper sidewall of each of the plugs is tapered;
a third insulating film formed above the second insulating film and having a third relative dielectric constant less than the second relative dielectric constant of the second insulating film;
a plurality of trenches extending through the second and the third insulating film and reaching an upper portion of each of the plugs; and
an interconnect wiring comprising metal formed within each of the trenches and contacting the upper portion of each of the plugs.

10. The device according to claim 9, wherein the second insulating film includes a silicon nitride.

11. The device according to claim 9, wherein each of the trenches partially extends into the upper portion of each of the plugs and an upper portion of the first insulating film.

12. A method of manufacturing a semiconductor device comprising:
forming a plurality of longitudinal holes through a first interlayer insulating film;
filling each of the holes with a columnar plug;
exposing upper sidewalls of the plugs by removing an upper portion of the first insulating film;
slimming the exposed plugs;
forming an etch stop film above upper surfaces of the plugs or between the upper sidewalls of the plugs;
forming a second interlayer insulating film above the etch stop film, the second interlayer insulating film having a higher etching selectivity to the etch stop film;
forming a plurality of trenches each reaching the etch stop film and each of the plugs; and
forming an interconnect wiring within each of the trenches, the interconnect wiring contacting the upper portion of each of the plugs.

13. The method according to claim 12, wherein slimming comprises anisotropic etching followed by isotropic etching.

14. The method according to claim 12, wherein the second interlayer insulating film has a relative dielectric constant that is less than a relative dielectric constant of the etch stop film.

15. The method according to claim 12, wherein the first interlayer insulating film includes a silicon oxide and the etch stop film includes a silicon nitride.

16. The method according to claim 12, wherein forming the etch stop film comprises depositing the etch stop film along the upper surfaces and the upper sidewalls of the plugs followed by entirely etching back the etch stop film.

17. The method according to claim 12, wherein forming the etch stop film comprises depositing the etch stop film along the upper surfaces and the upper sidewalls of the plugs followed by planarizing the etch stop film by chemical mechanical polishing using the upper surfaces of the plugs as a polish stop.

18. The method according to claim 12, wherein forming the etch stop film above the upper surfaces of the plugs comprises re-depositing a film being substantially homogenous with the first interlayer insulating film between the plugs followed by forming the etch stop film above the upper surfaces of the plugs.

19. The method according to claim 18, wherein re-depositing comprises depositing the film along the upper surfaces and the upper sidewalls of the plugs followed by entirely etching back the re-deposited film.

20. The method according to claim 18, wherein re-depositing comprises depositing the film along the upper surfaces and the upper sidewalls of the plugs followed by planarizing the re-deposited film by chemical mechanical polishing using the upper surfaces of the plugs as a polish stop.
